(19) United States
(12) Patent Application Publication
(10) Pub. No.: US 2013/0307078 A1
(43) Pub. Date: Nov. 21, 2013

(54) SILICON ON INSULATOR COMPLEMENTARY METAL OXIDE SEMICONDUCTOR WITH AN ISOLATION FORMED AT LOW TEMPERATURE

(71) Applicant: International Business Machines Corporation, Armonk, NY (US)

(72) Inventors: Kangguo Cheng, Schenectady, NY (US); Bruce B. Doris, Brewster, NY (US); Ali Khakifirooz, Mountain View, CA (US); Ghavam G. Shahidi, Pound Ridge, NY (US)

(73) Assignee: International Business Machines Corporation, Armonk, NY (US)

(21) Appl. No.: 13/949,606

(22) Filed: Jul. 24, 2013

Related U.S. Application Data
(62) Division of application No. 13/166,714, filed on Jun. 22, 2011.

(51) Int. Cl. H01L 29/06

(52) U.S. Cl. CPC H01L 29/0649
USPC 257/351

(57) ABSTRACT

A silicon on insulator (SOI) complementary metal oxide semiconductor (CMOS) with an isolation formed at a low temperature and methods for constructing the same. An example method includes infusing an insulation material at a low temperature to form a silicon-based insulator between the active regions.

This application is a divisional of and claims priority under 35 U.S.C. §120 to U.S. patent application Ser. No. 13/166,714 filed on Jun. 22, 2011, the entire text of which is specifically incorporated by reference herein.

### BACKGROUND

The present invention relates to manufacturing of silicon on insulator (SOI) complementary metal oxide semiconductor (CMOS), and, more particularly, to a technique for forming a high-quality isolation on an SOI CMOS performed at a lower temperature than a conventional shallow trench isolation (STI) process requires.

Extremely thin silicon on oxide (ETSOI) CMOS is a viable device option for future CMOS technology. ETSOI CMOS with an ultra-thin buried oxide (UTBOX) layer is particularly attractive as it provides flexibility for tuning device characteristics by applying doping and/or bias at the back side of the UTBOX layer. However, ETSOI CMOS devices present two technical issues.

A first challenge of an ETSOI CMOS is the difficulty associated with forming a robust isolation. The conventional STI technique uses SiO₂ deposited in a trench to form isolations between adjacent CMOS devices. However, SiO₂ is vulnerable to subsequent hydrofluoric (HF) acid etching processes because SiO₂ itself has a high wet etch rate. The erosion of SiO₂ in the trench during subsequent etching processes causes the formation of divots in the trench and a possible loss of the UTBOX layer, which interposes between the ETSOI layer and a substrate in the ETSOI CMOS. Without an isolation robustly sealing the UTBOX layer, the ETSOI CMOS is prone to malfunction due to potential shorts between the ETSOI layer and the substrate caused by the UTBOX layer being eroded in the HF acid processes.

On the other hand, as previously discussed, SiO₂ deposited in an STI trench has a high wet etch rate. To strengthen etch resistivity, a high temperature anneal is performed on the substrate to densify the SiO₂ deposited in the trench. However, the high temperature anneal may be incompatible with embedded dynamic random access memory (eDRAM) technology. The high temperature anneal may render the CMOS inoperative because the heat may cause excessive dopant diffusion in deep trench capacitors already formed in the ETSOI CMOS.

### BRIEF SUMMARY

An example of the present invention is a method for isolating devices on active regions on a silicon on insulator (SOI) complementary metal oxide semiconductor (CMOS). The SOI CMOS includes a substrate, an SOI layer and a buried oxide (BOX) layer interposed between the substrate and the SOI layer. The method includes infusing an insulation material at a low temperature to form a silicon-based insulator between the active regions.

Another example of the present invention is a CMOS. The CMOS includes a substrate. The CMOS also includes an SOI layer in which a plurality of active regions are defined. The active regions are configured to contain CMOS devices. The CMOS also includes a BOX layer interposed between the substrate and the SOI layer. The CMOS further includes at least one trench separating at least two of the active regions. The trench traverses the SOI layer, the BOX layer and a portion of the substrate. The CMOS further includes a first dielectric layer and a second dielectric layer. The first dielectric layer partially fills the trench from the bottom of the trench. The second dielectric layer partially fills the trench from the top of the first dielectric layer. The second dielectric layer is one of silicon-rich oxide and silicon-rich nitride.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIGS. 1A and 1B show an example method for isolating devices on active regions on a silicon on insulator (SOI) complementary metal oxide semiconductor (CMOS) contemplated by the present invention.

FIGS. 2A-2C show another example method for isolating devices on active regions on an SOI CMOS contemplated by the present invention.

FIG. 3 shows an example SOI CMOS contemplated by the present invention.

### DETAILED DESCRIPTION

The present invention is described with reference to embodiments of the invention. Throughout the description of the invention reference is made to Figures.

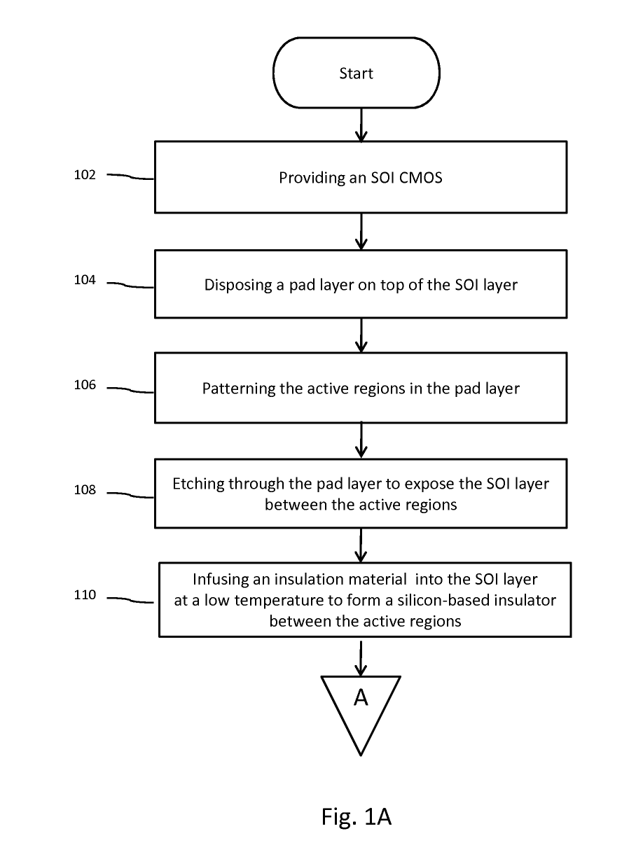

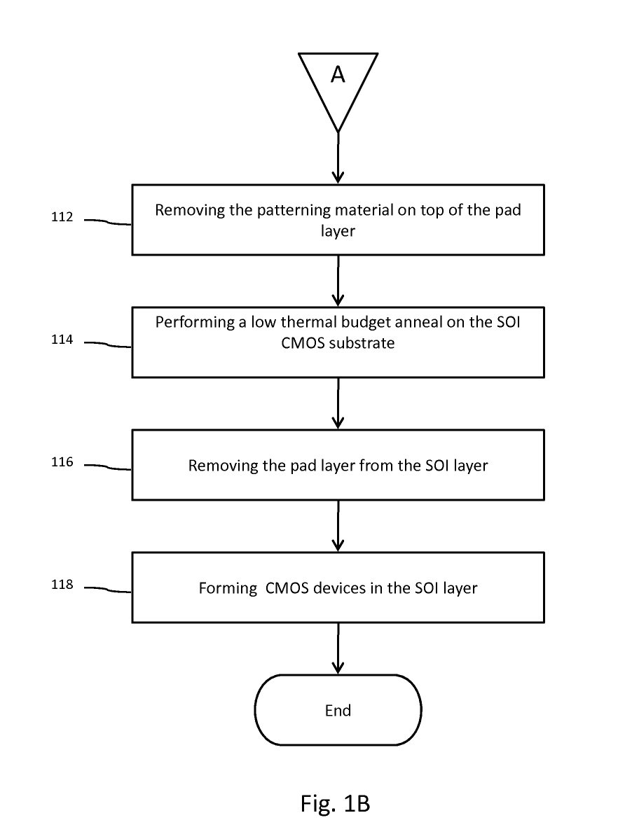

FIGS. 1A and 1B show a flowchart for a method of isolating devices on active regions on a silicon on insulator (SOI) complementary metal oxide semiconductor (CMOS) in accordance with an embodiment of the present invention. The example method starts with a providing step 102. An SOI CMOS is provided in this step. The SOI CMOS includes a substrate, an SOI layer and a buried on oxide (BOX) layer interposed between the substrate and the SOI layer.

In one embodiment, the SOI CMOS includes embedded dynamic random access memory (eDRAM) devices prebuilt in the substrate. After the SOI CMOS is provided, the process continues to a disposing step 104.

During the disposing step 104, a pad layer is disposed on top of the SOI layer. The composition of the pad layer depends on the type of insulation material infused into the SOI layer in a subsequent infusing step 110. In one embodiment in which nitrogen is infused into the SOI layer in the infusing step 110, the pad layer can be an oxide, e.g., thermal oxide and deposited oxide. Alternatively, if oxygen is infused into the SOI layer, the pad layer can be a nitride.

In yet another embodiment, the pad layer includes a bi-layer structure. For example, the pad layer includes a layer of nitride on top of a layer of oxide, or vice versa. The disposing step 104 is followed by a patterning step 106.

The patterning step 106 involves patterning the active regions in the pad layer. The active regions are areas in the SOI layer where CMOS devices, e.g., CMOS transistors, are fabricated. Silicon-based insulators are formed between the active regions to isolate the adjacent CMOS devices. The patterning step 106 can be performed by applying photoresists and lithography. After the patterning step 106 is completed, the process moves on to an etching step 108.

The etching step 108 involves etching through the pad layer to expose the SOI layer between the active regions where the CMOS devices are lodged. The etching step 108 can be performed by, for example, reactive-ion etching (RIE) or wet chemical etching. During the etching step 108, the pad layer on top of the SOI layer between the active regions defined by the patterning step 106 is etched away. After the etching step 108 is completed, the SOI layer between the active regions is exposed to undergo an infusing step 110.

During the infusing step 110, an insulation material is infused into the SOI layer between the active regions at a low temperature to form a silicon-based insulator between the active regions. In one embodiment, the insulation material is nitrogen, oxygen or a mixture of nitrogen and oxygen. Depending on the type of insulation material infused, the silicon-based insulator is silicon oxide when oxygen is infused; silicon nitride when nitrogen is infused; or a mixture of silicon nitride and silicon oxide when a mixture of nitrogen and oxygen is infused.

In another embodiment, the infusing step 110 is performed by gas cluster ion beam (GCIB) at a temperature less than 200 degrees Celsius. Detail about the GCIB technique can be found U.S. Pat. No. 7,785,978, incorporated herein by reference in its entirety. In addition to the GCIB, the infusing step 110 can be performed by one of implantation, plasma doping and plasma-based implantation at a temperature less than 200 degrees Celsius. After the infusing step 110 is completed, the process continues to a first removing step 112.

During the first removing step 112, the patterning material is removed from the top of the pad layer where the active regions are formed during the patterning step 106 and the etching step 108. In one embodiment, the photoresist is removed by liquid resist strippers and/or resist asking. After the first removing step 112 is completed, the process goes on to a performing step 114.

During the performing step 114, a low thermal budget anneal is performed on the substrate. In one embodiment, a low thermal anneal is performed at about 700 degrees Celsius for about 30 minutes. This operation improves the isolation quality. Moreover, the operation obviates the risk of early dopant diffusion, a side effect that plaques a process involving a high thermal budget anneal, in deep trench capacitors when eDRAM devices are prebuilt in the SOI CMOS. The performing step 114 is followed by a second removing step 116.

During the second removing step 116, the pad layer, which protects the underlying active regions in the SOI layer throughout the etching step 108, the infusing step 110, the first removing step 112 and the performing step 114, is removed from the SOI layer. After the removal of the pad layer during the second removing step 116, the active regions in the SOI layer are ready for a forming step 118.

During the forming step 118, CMOS devices are formed in the SOI layer. In one embodiment, the CMOS device is a CMOS transistor. The CMOS transistor comprises a gate, a spacer and source/drain (S/D). In another embodiment, the CMOS transistor further includes a raised S/D to lower S/D resistance.

In yet another embodiment, the SOI CMOS discussed above is an extremely thin silicon on oxide (ETSOI) CMOS. In this embodiment, the SOI layer is an ETSOI layer. The thickness of the ETSOI layer is greater than 2 nm and less than 10 nm. In this embodiment, the ETSOI CMOS includes the substrate, the ETSOI layer and the BOX layer interposed between the substrate and the ETSOI layer. A plurality of active regions are defined in the ETSOI layer. In this embodiment, the CMOS devices are formed in the ETSOI layer. In one embodiment, the CMOS device formed in the ETSOI layer is a CMOS transistor.

In yet another embodiment, the BOX layer discussed above is an ultra-thin buried oxide (UTBOX) layer. In this embodiment, the ETSOI CMOS discussed above includes the substrate, the ETSOI layer and the UTBOX layer interposed between the substrate and the ETSOI layer.

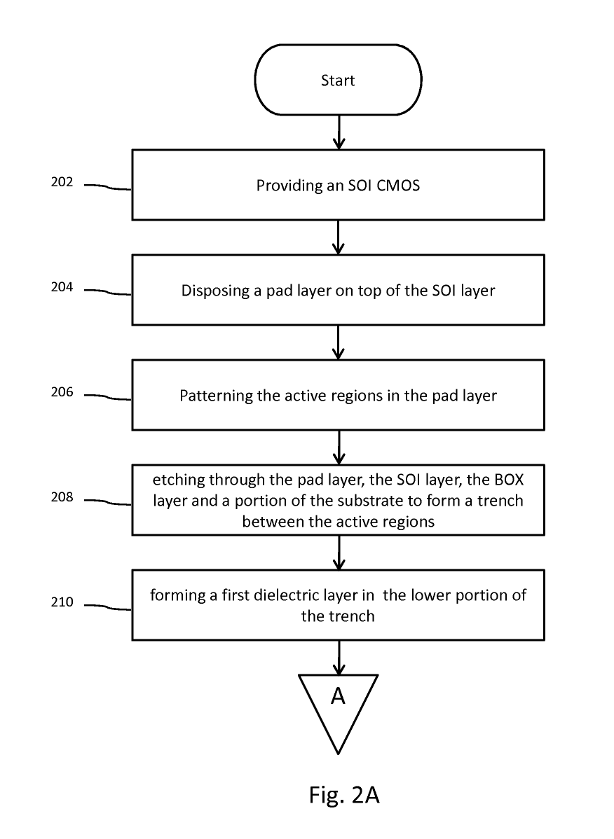

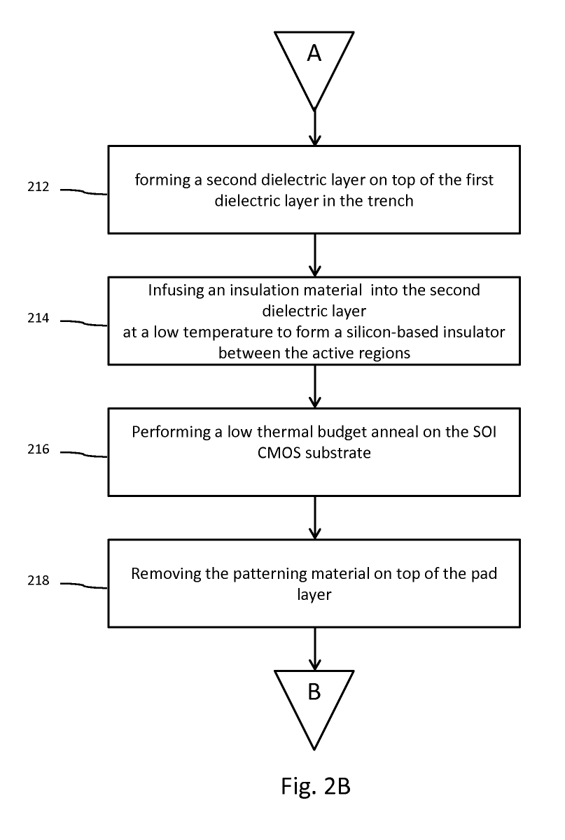

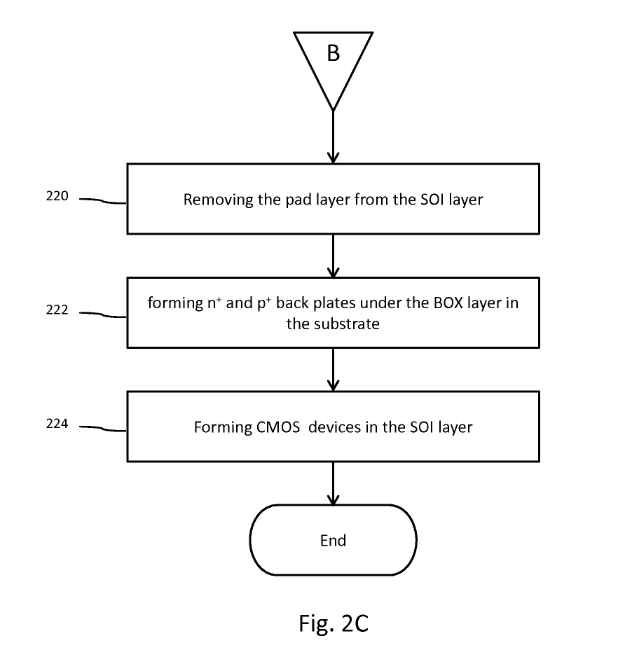

Turning to FIGS. 2A-2C, a flowchart of a method for isolating devices on active regions on an SOI CMOS in accordance with another embodiment of the present invention is shown. The example method starts with a providing step 202. A SOI CMOS is provided in this step. The SOI CMOS includes a substrate, an SOI layer and a BOX layer interposed between the substrate and the SOI layer.

In one embodiment, the SOI CMOS has eDRAM devices prebuilt in the substrate. After the SOI CMOS is provided, the process continues to a disposing step 204.

During the disposing step 204, a pad layer is disposed on top of the SOI layer. The composition of the pad layer depends on the type of insulation material infused into the SOI layer in a subsequent infusing step 214. In one embodiment, in which nitrogen is infused into the SOI layer in the infusing step 214, the pad layer can be an oxide, e.g., thermal oxide and deposited oxide. Alternatively, if oxygen is infused into the SOI layer, the pad layer can be a nitride.

In yet another embodiment, the pad layer includes a bi-layer structure. For example, the pad layer includes a layer of nitride on top of a layer of oxide, or vice versa. The disposing step 204 is followed by a patterning step 206.

The patterning step 206 involves patterning the active regions in the pad layer. The active regions are areas in the SOI layer where CMOS devices, e.g., CMOS transistors, are fabricated. Silicon-based insulators are formed between the active regions to isolate the adjacent CMOS devices. The patterning step 206 can be performed by applying photoresists and lithography. After the patterning step 206 is completed, the process moves on to an etching step 208.

During the etching step 208, a trench is formed between the active regions by etching through the pad layer, the SOI layer, the BOX layer and a portion of the substrate. The etching step 208 can be performed by one of reactive-ion etching (RIE) and wet chemical etching. During this operation, the pad layer on top of the SOI layer between the active regions defined by the patterning step 206, the SOI layer between the active regions, the BOX layer between the active regions and a portion of the substrate between the active regions are etched away. The trench thus formed traverses the SOI layer, the BOX layer and a portion of the substrate and separates at least two of the active regions. After the etching step 208 is completed, the trench is ready to undergo a first forming step 210 and a second forming step 212.

During the first forming step 210, a first dielectric layer is formed in the lower portion of the trench. The first dielectric layer can be an oxide. In one embodiment, the oxide is deposited in the lower portion of the trench by chemical deposition.

In another embodiment, the first dielectric layer is recessed such that it partially fills the trench from the bottom of the trench up to a level below the lower side of the BOX layer. In this embodiment, recessing the first dielectric layer is performed by wet chemical etching or RIE. After the first forming step 210 is completed, the second forming step 212 follows.

During the second forming step 212, a second dielectric layer is formed on top of the first dielectric layer in the trench. The second dielectric layer is one of polycrystalline silicon (polysilicon) and amorphous silicon (a-Si). In one embodiment, the polysilicon or a-Si is deposited on top of the first dielectric layer by chemical deposition.

In another embodiment, the second dielectric layer is recessed such that it partially fills the trench from the top of the first dielectric layer up to a level substantially aligned with the top of the SOI layer. In this embodiment, recessing the second dielectric layer is performed by chemical etching or RIE. In this embodiment, the top of the second dielectric layer can be between the upper side and the lower side of the SOI layer. Alternatively, the top of the second dielectric layer can be above or as high as the top of the SOI layer. In this embodiment, the BOX layer is sealed by the second dielectric layers along two sides and by the SOI layer and the substrate along the other two sides from being damaged by hydrofluoric (HF) acid etching process. After the second forming step 212 is completed, the process continues to an infusing step 214.

During the infusing step 214, an insulation material is infused into the second dielectric layer at a low temperature to form a silicon-based insulator between the active regions. In one embodiment, oxygen is infused into the second dielectric layer. The silicon-based insulator thus formed is a silicon oxide. Preferably, the silicon oxide is a silicon-rich oxide, i.e., SiOₓ, where x is less than two.

In an alternative embodiment, nitrogen is infused into the second dielectric layer. The silicon-based insulator thus formed is a silicon nitride. Preferably, the silicon nitride is a silicon-rich nitride, i.e., Si₃Nₓ, where x is less than four. In these embodiments, the silicon-rich oxide or silicon-rich nitride has better etch resistance to HF acid etching conventionally employed in transistor forming processes than SiO₂ or Si₃N₄, respectively.

As previously discussed, the infusing step 214 can be performed by gas cluster ion beam (GCIB) at a temperature less than 200 degrees Celsius. In addition to the GCIB, the infusing step 214 can be performed by implantation, plasma doping and/or plasma-based implantation at a temperature less than 200 degrees Celsius. After the infusing step 214 is completed, the process continues to a performing step 216.

During the performing step 216, a low thermal budget anneal is performed on the substrate. In one embodiment, a low thermal anneal is performed at about 700 degrees Celsius for about 30 minutes. This operation improves the isolation quality. Moreover, the operation obviates the risk of early dopant diffusion, a side effect of a high thermal budget anneal, in deep trench capacitors when eDRAM devices are prebuilt in the SOI CMOS. The performing step 216 is followed by a first removing step 218 and a second removing step 220.

During the first removing step 218, the patterning material is removed from the top of the pad layer where the active regions are defined during the patterning step 206 and the etching step 208. In one embodiment, the photoresist is removed by liquid resist strippers and/or resist asking. After the first removing step 218 is completed, the process continues to the second removing step 220.

During the second removing step 220, the pad layer, which protects the active regions in the SOI layer throughout the etching step 208, the two forming steps 210, 212, the infusing step 214, the performing step 216 and the first removing step 218, is removed from the SOI layer. After the removal of the pad layer during the second removing step 220, the SOI CMOS is ready for two subsequent forming steps 222, 224.

During the first forming step 222, n⁺ and p⁺ back plates are formed under the BOX layer in the substrate. In one embodiment, an ion implantation is performed to dope the substrate. N-type dopants include arsenic and phosphorous. P-type dopants include boron and iridium. After the completion of the first forming step 222, the process proceeds to a second forming step 224.

During the second forming step 224, CMOS devices are formed in the active regions in the SOI layer. In one embodiment, the CMOS device is a CMOS transistor. The CMOS transistor includes a gate, a spacer and a source/drain (S/D). In another embodiment, the CMOS transistor further includes a raised S/D to lower the S/D resistance.

In one embodiment, the SOI CMOS discussed above is an extremely thin silicon on oxide (ETSOI) CMOS. In this embodiment, the SOI layer discussed above is an ETSOI layer. The thickness of the ETSOI layer is greater than 2 nm and less than 10 nm. In this embodiment, the ETSOI CMOS includes the substrate, the ETSOI layer and the BOX layer interposed between the substrate and the ETSOI layer. A plurality of active regions are defined in the ETSOI layer. In this embodiment, the CMOS devices are formed in the ETSOI layer. In one embodiment, the CMOS device formed in the ETSOI layer is a CMOS transistor.

In another embodiment, the BOX layer discussed above is an ultra-thin buried oxide (UTBOX) layer. In this embodiment, the ETSOI CMOS discussed above includes the substrate, the ETSOI layer and the UTBOX layer interposed between the substrate and the ETSOI layer. In this embodiment, the trench traverses the ETSOI layer, the UTBOX layer and a portion of the substrate. In this embodiment, the UTBOX layer is sealed by the second dielectric layers along two sides and by the ETSOI layer and the substrate along the other two sides from being damaged by hydrofluoric HF acid etching processes.

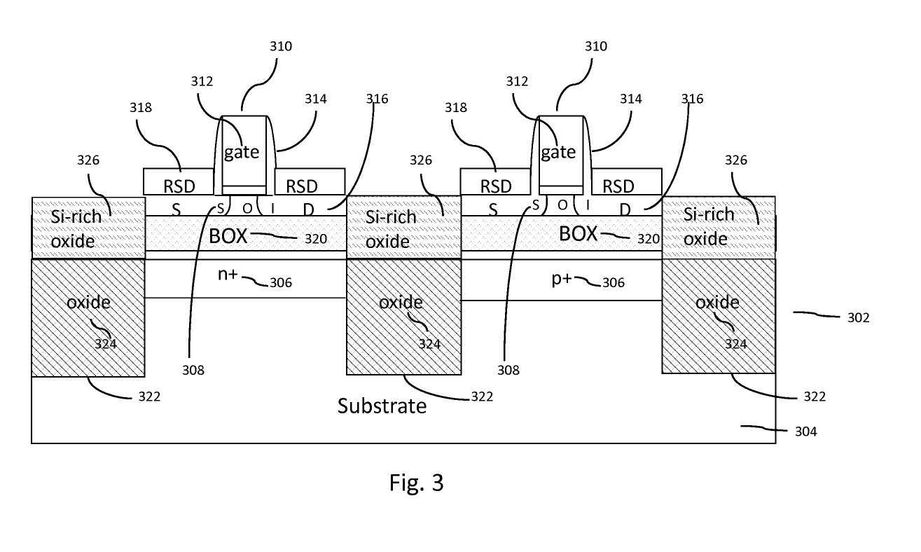

FIG. 3 shows a cross section of an example CMOS 302 contemplated by the present invention. The CMOS 302 includes a substrate 304. In one embodiment, the CMOS 302 includes n⁺ and p⁺ back plates 306 under the BOX layer 320 in the substrate 304. The n⁺ back plates 306 are formed by implanting n-type dopants including arsenic and phosphorous. The p⁺ back plates 306 are formed by implanting p-type dopants including boron and iridium.

In another embodiment, the CMOS 302 includes eDRAM devices (not shown in FIG. 3) prebuilt in the substrate 304.

The CMOS 302 further includes a silicon on oxide (SOI) layer 308. A plurality of active regions 308 are defined in the SOI layer 308. The active regions 308 are configured to contain CMOS devices 310. In one embodiment, the CMOS device 310 is a CMOS transistor 310. The CMOS transistor 310 includes a gate 312, a spacer 314 and a source/drain(S/D) 316. In another embodiment, the CMOS transistor 310 further includes a raised S/D 318 to lower the S/D 316 resistance.

The CMOS 302 further includes a buried oxide (BOX) layer 320 interposed between the substrate 304 and the SOI layer 308.

The CMOS 302 further includes at least one trench 322 separating at least two of the active regions 308. In one embodiment, the trench 322 traverses the SOI layer 308, the BOX layer 320 and a portion of the substrate 304.

The CMOS 302 further includes a first dielectric layer 324. In one embodiment, the first dielectric layer 324 is an oxide that partially fills the trench 322 from the bottom of the trench 322.

In another embodiment, the first dielectric layer 324 partially fills the trench 322 from the bottom of the trench 322 up to a level below the lower side of the BOX layer 320.

The CMOS 302 further includes a second dielectric layer 326 on top of the first dielectric layer 324. In one embodiment, the second dielectric layer 326 is silicon-rich oxide, i.e., SiOₓ, x being less than two, or silicon-rich nitride, i.e., Si₃Oₓ, x being less than four.

In another embodiment, the second dielectric layer 326 partially fills the trench 322 from the top of the first dielectric layer 324 up to a level substantially aligned with the top of the SOI layer 308. In this embodiment, the top of the second dielectric layer 326 can be between the upper side and the lower side of the SOI layer 308. Alternatively, the top of the second dielectric layer 326 can be above or as high as the top of the SOI layer 308. In the embodiments discussed above, the BOX layer 320 is sealed by the second dielectric layers 326 along two sides and by the SOI layer 308 and the substrate 304 along the other two sides.

In one embodiment, the SOI layer 308 is an ETSOI layer 308. The thickness of the ETSOI layer 308 is greater than 2 nm and less than 10 nm. In this embodiment, the CMOS 302 includes the substrate 304, the ETSOI layer 308 and the BOX layer 320 interposed between the substrate 304 and the ETSOI layer 308. In this embodiment, the trench 322 traverses the ETSOI layer 308, the BOX layer 320 and a portion of the substrate 304. A plurality of active regions 308 are defined in the ETSOI layer 308. In this embodiment, the CMOS devices 310 are formed in the ETSOI layer 308. In one embodiment, the CMOS device 310 is a CMOS transistor 310.

In yet another embodiment, the BOX layer 320 is an ultra-thin buried oxide (UTBOX) layer 320. The CMOS 302 includes the substrate 304, the ETSOI layer 308 and the UTBOX layer 320 interposed between the substrate 304 and the ETSOI layer 308. In this embodiment, the trench 322 traverses the ETSOI layer 308, the UTBOX layer 320 and a portion of the substrate 304. In this embodiment, the UTBOX layer 320 is sealed by the second dielectric layers 326 along two sides and by the ETSOI layer 308 and the substrate 304 along the other two sides.

While the preferred embodiments to the invention have been described, it will be understood that those skilled in the art, both now and in the future, may make various improvements and enhancements that fall within the scope of the claims which follow. These claims should be construed to maintain the proper protection for the invention first described.

What is claimed is:

1. A complementary metal oxide semiconductor (CMOS),
comprising:
a substrate;
a silicon on oxide (SOI) layer in which a plurality of active regions are defined, the active regions being configured to contain CMOS devices;
a buried oxide (BOX) layer interposed between the substrate and the SOI layer;
at least one trench separating at least two of the active regions, wherein the trench traverses the SOI layer, the BOX layer and a portion of the substrate;
a first dielectric layer that partially fills the trench from the bottom of the trench; and
a second dielectric layer that partially fills the trench from the top of the first dielectric layer,
wherein the second dielectric layer is one of SiOₓ, x being less than two, and Si₃Nₓ, x being less than four.

2. The CMOS of claim 1, wherein:
the first dielectric layer partially fills the trench from the bottom of the trench up to a level below the lower side of the BOX layer; and
the second dielectric layer partially fills the trench from the top of the first dielectric layer up to a level substantially aligned with the top of the SOI layer.

3. The CMOS of claim 1, further comprising:
the CMOS devices in the active regions; and
n⁺ and p⁺ back gates under the BOX layer in the substrate.

4. The CMOS of claim 1, wherein:
the SOI layer is an ETSOI layer; and
the CMOS includes the substrate, the ETSOI layer and the BOX layer interposed between the substrate and the ETSOI layer.

5. The CMOS of claim 1, wherein:
the BOX layer is an ultra-thin buried oxide (UTBOX) layer; and
the CMOS includes the substrate, the ETSOI layer and the UTBOX layer interposed between the substrate and the ETSOI layer.
